(19) United States
(12) Patent Application Publication
(10) Pub. No.: US 2024/0356522 A1
(43) Pub. Date: Oct. 24, 2024

(54) ELASTIC WAVE ELEMENT, DEMULTIPLEXER, AND COMMUNICATION DEVICE

(71) Applicant: KYOCERA Corporation, Kyoto-shi, Kyoto (JP)

(72) Inventor: Motoki ITO, Ikoma-shi (JP)

(73) Assignee: KYOCERA Corporation, Kyoto-shi, Kyoto (JP)

(21) Appl. No.: 18/687,518

(22) PCT Filed: Aug. 31, 2022
(86) PCT No.: PCT/JP2022/032738

§ 371 Date: Feb. 28, 2024

(30) Foreign Application Priority Data
Aug. 31, 2021 (JP) 2021-141510

(51) Int. Cl. H03H 9/145; H03H 9/02; H03H 9/25; H03H 9/64; H03H 9/72

(52) U.S. Cl. CPC H03H 9/14544; H03H 9/02559; H03H 9/02574; H03H 9/02637; H03H 9/02866; H03H 9/25; H03H 9/6483; H03H 9/725

(57) ABSTRACT

An acoustic wave device includes a piezoelectric layer made of a piezoelectric crystal and an interdigital transducer (IDT) electrode on an upper surface of the piezoelectric layer. The IDT electrode includes multiple electrode fingers. A normalized thickness D1/p of the piezoelectric layer and a duty d of the IDT electrode have a relationship expressed by 0.166≤d×D1/p≤0.241 . . . (1), where p is a repetition interval between centers of the multiple electrode fingers, and D1 is a thickness of the piezoelectric layer.

### TECHNICAL FIELD

The present disclosure relates to an acoustic wave device as an electronic component that uses acoustic waves, a duplexer including the acoustic wave device, and a communication apparatus.

### BACKGROUND OF INVENTION

A known acoustic wave device applies a voltage to an interdigital transducer (IDT) electrode on a piezoelectric body to generate an acoustic wave that propagates through the piezoelectric body. The IDT electrode includes two comb-shaped electrodes. The two comb-shaped electrodes each include multiple electrode fingers, which correspond to teeth of a comb, and are interleaved with each other. In the acoustic wave device, a standing wave of the acoustic wave that has a wavelength equal to two times the pitch of the electrode fingers is formed. The frequency of the standing wave serves as a resonance frequency. Therefore, the resonance point of the acoustic wave device is defined by the pitch of the electrode fingers.

### CITATION LIST

### Patent Literature

Patent Literature 1: Japanese Unexamined Patent Application Publication No. 2019-154065

### SUMMARY

In an embodiment of the present disclosure, an acoustic wave device includes a piezoelectric layer and an IDT electrode. The piezoelectric layer is made of a piezoelectric crystal. The IDT electrode is located on an upper surface of the piezoelectric layer and includes multiple electrode fingers. A normalized thickness D1/p of the piezoelectric layer and a duty d of the IDT electrode have a relationship expressed by

$$0.166 \leq d \times D 1 / p \leq 0.241 , \qquad ( 1 )$$

where p is a repetition interval between centers of the multiple electrode fingers, and D1 is a thickness of the piezoelectric layer.

In an embodiment of the present disclosure, an acoustic wave device includes a piezoelectric layer, an IDT electrode, and a multilayer film. The piezoelectric layer is made of a piezoelectric crystal. The IDT electrode is located on an upper surface of the piezoelectric layer and includes multiple electrode fingers. The multilayer film is located on a lower surface side of the piezoelectric layer and includes at least one low acoustic impedance layer and at least one high acoustic impedance layer alternated with each other. A normalized thickness D2/p of the low acoustic impedance layer and a duty d of the IDT electrode have a relationship expressed by

$$0.060 \leq d \times D 2 / p \leq 0 \text{.087} , \qquad ( 2 )$$

where p is a repetition interval between centers of the multiple electrode fingers, and D2 is a thickness of the low acoustic impedance layer.

In an embodiment of the present disclosure, an acoustic wave device includes a piezoelectric layer, an IDT electrode, and a multilayer film. The piezoelectric layer is made of a piezoelectric crystal. The IDT electrode is located on an upper surface of the piezoelectric layer and includes multiple electrode fingers. The multilayer film is located on a lower surface side of the piezoelectric layer and includes at least one low acoustic impedance layer and at least one high acoustic impedance layer alternated with each other. A normalized thickness D3/p of the high acoustic impedance layer and a duty d of the IDT electrode have a relationship expressed by

$$0.076 \leq d \times D 3 / p \leq 0.1 \; 11 , \qquad ( 3 )$$

where p is a repetition interval between centers of the multiple electrode fingers, and D3 is a thickness of the high acoustic impedance layer.

In an embodiment of the present disclosure, a duplexer includes an antenna terminal, a transmit filter, and a receive filter. The transmit filter is configured to filter a signal to be outputted to the antenna terminal. The receive filter is configured to filter a signal inputted from the antenna terminal. At least one of the transmit filter or the receive filter includes the above-described acoustic wave device.

In an embodiment of the present disclosure, a communication apparatus includes an antenna, the above-described duplexer with the antenna terminal connected to the antenna, and an integrated circuit (IC) connected to the transmit filter and the receive filter. The IC and the antenna terminal are located at opposite sides of the transmit and receive filters in a signal path.

### BRIEF DESCRIPTION OF THE DRAWINGS

FIG. 1 is a schematic sectional view of an acoustic wave device according to an embodiment of the present disclosure.

FIG. 2 is a plan view of the acoustic wave device of FIG. 1.

FIG. 3 is a diagram illustrating simulation results in the embodiment of the present disclosure.

FIG. 4 is a graph illustrating maximum phases of spurious components in a band A in the simulation results in the embodiment of the present disclosure.

FIG. 5 is a schematic sectional view of an acoustic wave device according to another embodiment of the present disclosure.

FIG. 6 is a schematic sectional view of an acoustic wave device according to further another embodiment of the present disclosure.

FIG. 7 is a schematic diagram of a duplexer as an exemplary application of the acoustic wave device according to any of the embodiments of the present disclosure.

FIG. 8 is a block diagram illustrating the configuration of an essential part of a communication apparatus as an exemplary application of the duplexer of FIG. 7.

### DESCRIPTION OF EMBODIMENTS

Embodiments of the present disclosure will be described below with reference to the drawings. Note that the figures used in the following description are schematic, and the dimensions, ratios, and so forth on the figures do not necessarily correspond to actual ones. The above-described note does not deny that the actual shape and/or dimension may be as shown in the figures or that the features of shape and/or dimension may be extracted from the figures.

Some figures include an orthogonal coordinate system including an AX1 axis, an AX2 axis, and an AX3 axis for the sake of convenience. In an acoustic wave device according to the present disclosure, any direction may be upward or downward. For the sake of convenience, a direction along the AX3 axis may be an up-down direction, and a directional term, such as an upper surface or a lower surface, may be used. The AX1 axis is defined as being perpendicular to a propagation direction of an acoustic wave propagating along an upper surface of a piezoelectric layer 2, which will be described later. The AX2 axis is defined as being parallel to the upper surface of the piezoelectric layer 2 and being perpendicular to the AX1 axis. The AX3 axis is defined as being perpendicular to the upper surface of the piezoelectric layer 2.

The embodiments described herein are illustrative. Partial substitutions may be made between different embodiments and different examples. Different embodiments and different examples may be partially combined.

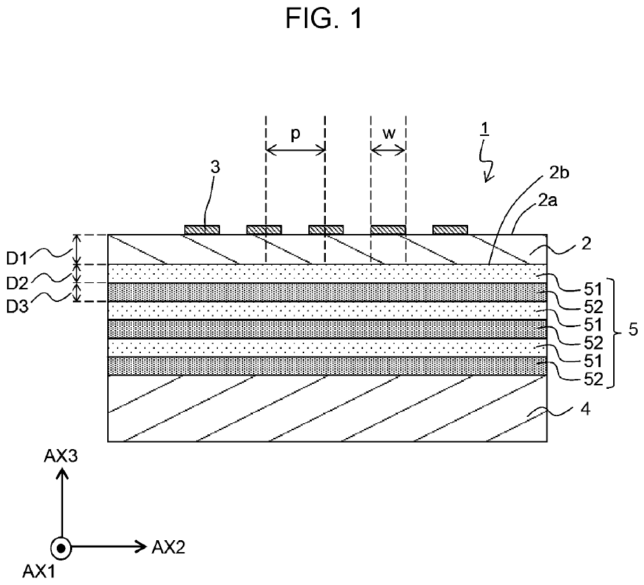

FIG. 1 is a schematic sectional view of an acoustic wave device 1 according to an embodiment of the present disclosure.

In the embodiment, as illustrated in FIG. 1, the acoustic wave device 1 includes the piezoelectric layer 2, an IDT electrode 3, a supporting substrate 4, and a multilayer film 5. The supporting substrate 4, the multilayer film 5, and the piezoelectric layer 2 are stacked in that order.

The acoustic wave device 1 uses an acoustic wave propagating through the piezoelectric layer 2. The acoustic wave used by the acoustic wave device 1 may be of an appropriate type. For example, the acoustic wave may be a bulk wave, which includes a plate wave in a broad concept, or may be a surface acoustic wave or a boundary acoustic wave, which are not necessarily clearly distinguishable from each other. The plate wave may be a Lamb wave mainly including a component (P component) in the propagation direction and/or a component (SV component) in a thickness direction along the thickness of the piezoelectric layer or may be an SH wave mainly including a component (SH component) in a direction perpendicular to the propagation direction and horizontal to a surface of the piezoelectric layer. The Lamb wave may be in a symmetric mode (S mode) or may be in an antisymmetric mode (A mode). The A mode may be an A0 mode in which the number of nodes in the thickness direction is 0 or may be an A1 mode in which the number of nodes in the thickness direction is 1. In the description of embodiments, an embodiment in which a plate wave having a relatively high velocity is used as an acoustic wave may be described as an example unless otherwise specified. In another point of view, an embodiment in which the resonance frequency is relatively high (e.g., 4 GHz or more or 5 GHz or more) may be described as an example.

In this example, the supporting substrate 4 supports the multilayer film 5 and the piezoelectric layer 2, which are stacked on the supporting substrate 4. The supporting substrate 4 may be made of any material having a certain strength. For example, if the supporting substrate 4 is made of a material having a smaller coefficient of linear expansion than the piezoelectric layer 2, reducing deformation of the piezoelectric layer 2 caused by temperature change can reduce characteristic change due to temperature change. The supporting substrate 4 may be made of a material that allows the acoustic wave propagating therethrough to have a higher transverse wave acoustic velocity than the acoustic wave propagating through the piezoelectric layer 2. If the supporting substrate 4 is made of a selected material that allows the acoustic wave propagating therethrough to have a higher transverse wave acoustic velocity than the acoustic wave propagating through the piezoelectric layer 2, the acoustic wave can be trapped in the piezoelectric layer 2. Thus, the acoustic wave device 1 with excellent frequency characteristics can be provided.

Examples of such a material include sapphire (Al₂O₃) and silicon (Si). In the embodiment, the supporting substrate 4 made of Si will be described as an example.

The supporting substrate 4 may have any thickness, for example, a larger thickness than the piezoelectric layer 2, which will be described below.

The piezoelectric layer 2 includes an upper surface 2a and a lower surface 2b, which are perpendicular to the AX3 axis extending in the up-down direction. The above-described supporting substrate 4 is located adjacent to the lower surface 2b. The lower surface 2b may be in direct contact with the supporting substrate 4 or may be in indirect contact with the supporting substrate 4 such that, for example, the multilayer film 5, which will be described later, and an adhesive layer (not illustrated) are located between the lower surface 2b and the supporting substrate 4. The IDT electrode 3, which will be described later, is located on the upper surface 2a.

Usable examples of the piezoelectric layer 2 include a piezoelectric monocrystalline substrate made of a lithium tantalate (LiTaO₃; hereinafter, referred to as LT) crystal and a piezoelectric monocrystalline substrate made of a lithium niobate (LiNbO₃) crystal. In the embodiment, specifically, the piezoelectric layer 2 includes a 114° Y-cut, X-propagation LT substrate.

The thickness of the piezoelectric layer 2 is defined as D1.

The IDT electrode 3 is located on the upper surface 2a of the piezoelectric layer 2. The IDT electrode 3 is made of a conductive material. As a material for the IDT electrode 3, various conductive materials such as Al, Cu, Pt, Mo, Au, and alloys thereof can be used. The IDT electrode 3 may include a stack of layers made of such materials. If the IDT electrode 3 includes a stack of layers, an underlying layer (not illustrated) may be disposed at each interface between the stacked layers. For example, the IDT electrode 3 may be made of Al, and the underlying layer may be made of Ti.

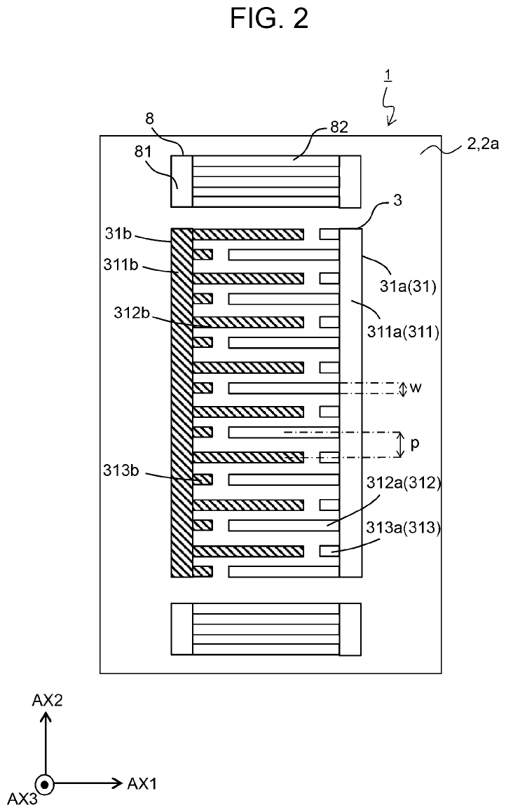

FIG. 2 illustrates the shape of the IDT electrode 3. As illustrated in FIG. 2, the IDT electrode 3 includes, for example, two comb-shaped electrodes 31 (31a and 31b), and is included in a resonator.

The comb-shaped electrodes 31 include two bus bars 311 (311a and 311b) and multiple long electrode fingers 312 (312a and 312b), which are connected to either of the bus bars 311. The electrode fingers 312a connected to one bus bar 311a and the electrode fingers 312b connected to the other bus bar 311b are alternately arranged. The comb-shaped electrodes 31 further include multiple dummy electrodes 313 (313a and 313b). The dummy electrodes 313 face the tips of the electrode fingers 312 connected to one of the bus bars 311 and are connected to the other one of the bus bars 311.

The multiple electrode fingers 312 have, for example, the same length. The IDT electrode 3 may be apodized such that the length (overlap width in another point of view) of each of the multiple electrode fingers 312 depends on position in the propagation direction. The length and thickness of each of the electrode fingers 312 may be appropriately set in consideration of, for example, electrical characteristics required.

A repetition interval between the centers of the electrode fingers 312a and 312b is defined as a pitch p, and the width of each electrode finger 312 is defined as w. A duty d of the IDT electrode 3 represents the ratio of the width of the electrode finger to the pitch. In other words, the duty d of the IDT electrode 3 can be expressed as w/p. In obtaining the duty d, the unit of w is the same as that of p. For example, w and p are in units of μm.

The pitch p and the electrode finger width w each represent a mean value in the acoustic wave device 1 (i.e., the multiple electrode fingers 312 included in one IDT electrode 3). A specific portion, such as a portion from which one to three electrode fingers 312 are removed for fine adjustment of characteristics, may be removed from a target of calculation of the mean values. If each electrode finger 312 varies in width in its longitudinal direction (along the AX1 axis), an average width in an overlap region (defined by a line connecting the tips of the multiple electrode fingers 312a and a line connecting the tips of the multiple electrode fingers 312b) may be used.

Upon application of a radio frequency signal to the IDT electrode 3, a standing wave having a half-wavelength corresponding to the pitch p of the electrode fingers 312 is excited.

Two reflectors 8 are located at opposite sides of the IDT electrode 3 in the acoustic wave propagation direction. The reflectors 8 each include a pair of reflector bus bars 81 facing each other and multiple strip electrodes 82 extending between the pair of reflector bus bars 81.

The multilayer film 5 is located between the supporting substrate 4 and the piezoelectric layer 2. The multilayer film 5 includes low acoustic impedance layers 51 and high acoustic impedance layers 52, which are alternated with each other. The low acoustic impedance layers 51 have an acoustic impedance lower than that of the piezoelectric layer 2. The high acoustic impedance layers 52 have an acoustic impedance higher than that of the low acoustic impedance layers 51. The acoustic impedance of the high acoustic impedance layers 52 may be higher than, equal to, or lower than that of the piezoelectric layer 2.

In the multilayer film 5 with such a configuration, the reflectivity of the acoustic wave is relatively high at the interface of the low acoustic impedance layer 51 and the high acoustic impedance layer 52. This results in, for example, a reduction in leakage in the thickness direction of the acoustic wave propagating through the piezoelectric layer 2.

The acoustic impedances of the layers to be compared may be related to, for example, bulk waves propagating through the layers. Broadly speaking, the bulk waves include three types of waves, a longitudinal wave, a slow transverse wave, and a fast transverse wave. The slow transverse wave or the fast transverse wave is, for example, either one of a shear vertical (SV) wave and a shear vertical (SH) wave. The bulk wave used to obtain an acoustic impedance may be, for example, among the above-described three types of bulk waves, a bulk wave that propagates through the piezoelectric layer 2 and corresponds to a main component included in an acoustic wave intended to be used. The reason is that the multilayer film 5 is expected to trap an acoustic wave propagating through the piezoelectric layer 2 as described above. For example, if an acoustic wave intended to be used in the piezoelectric layer 2 mainly includes the SH wave, an SH-wave related acoustic impedance of the piezoelectric layer 2 and an SH-wave related acoustic impedance of the low acoustic impedance layers 51 may be compared. Although the SH wave has been described as an example, the same applies to the SV wave or the longitudinal wave. If an acoustic wave including longitudinal and transverse waves combined is intended to be used, for example, transverse-wave related acoustic impedances may be compared.

Conditions for comparison do not necessarily have to be tightened as described above. In another point of view, the acoustic impedances of the layers to be compared with each other do not be strictly specified. For example, in comparison between transverse-wave related acoustic impedances of two layers, as long as the difference between a fast-transverse-wave related acoustic impedance and a slow-transverse-wave related acoustic impedance of each layer is relatively small and as long as the magnitude relationship between the acoustic impedances of the two layers is clear if the fast transverse wave and the slow transverse wave are not particularly distinguished from each other, the fast transverse wave and the slow transverse wave do not have to be distinguished from each other. In another point of view, a component mainly included in the acoustic wave intended to be used in the piezoelectric layer 2 does not need to be strictly specified.

The acoustic impedance of the piezoelectric layer 2 depends on, for example, direction (cut angle). The acoustic impedance of the piezoelectric layer 2 may be affected by another layer. These may occur in other layers. In comparison between the acoustic impedances of layers, therefore, the acoustic impedances related to propagation in the direction along the AX2 axis may be compared on the assumption that, for example, the layers have the same configuration (e.g., cut angle) as that in an actual product. The acoustic impedance of the piezoelectric layer 2 may be affected by the shape of the IDT electrode 3, and may depend on position within a region where the piezoelectric layer 2 overlaps the IDT electrode 3. In this case, for example, a mean value in the above-described overlap region may be used.

The cut angle and the influence of, for example, the IDT electrode 3, do not necessarily need to be taken into consideration. In another point of view, the acoustic impedances of layers to be compared do not need to be strictly determined. For example, when it is clear that the acoustic impedance of the low acoustic impedance layers 51 is lower than that of the piezoelectric layer 2 independently of, for example, the cut angle of the piezoelectric layer 2, the acoustic impedances do not need to be determined on the assumption that the layers have the same configuration as that in an actual product. For example, when it is clear that the acoustic impedance of the low acoustic impedance layers 51 is lower than that of the piezoelectric layer 2 regardless of the presence or absence of the influence of the IDT electrode 3 or when it is clear that the acoustic impedance of the low acoustic impedance layers 51 is lower than that of the piezoelectric layer 2 in the same region in perspective plan view, the acoustic impedances in the overlap region do not need to be strictly obtained. In such cases, the acoustic impedances may be calculated based on, for example, densities and Young's moduli by using a simple theoretical formula and be compared with each other.

The above-described notes for comparison between the acoustic impedances may be used for the transverse wave acoustic velocity explained in the description of the supporting substrate 4 and an acoustic velocity in an intermediate layer 6, which will be described later.

The number of layers included in the multilayer film 5 may be set as appropriate. For example, the total number of layers including the low acoustic impedance layers 51 and the high acoustic impedance layers 52 of the multilayer film 5 may be greater than or equal to 3 and less than or equal to 12. The multilayer film 5 may include two layers in total, namely, one low acoustic impedance layer 51 and one high acoustic impedance layer 52. Although the total number of layers included in the multilayer film 5 may be an even number or an odd number, a layer adjoining the piezoelectric layer 2 is the low acoustic impedance layer 51. A layer adjoining the supporting substrate 4 may be the low acoustic impedance layer 51 or may be the high acoustic impedance layer 52.

Examples of a material for the low acoustic impedance layer 51 include silicon oxide (SiO₂). Examples of a material for the high acoustic impedance layer 52 include tantalum oxide (Ta₂Os), hafnium oxide (HfO₂), zirconium oxide (ZrO₂), titanium oxide (TiO₂), and magnesium oxide (MgO). In the embodiment, a configuration in which SiO₂ is used as the low acoustic impedance layer 51 and HfO₂ is used as the high acoustic impedance layer 52 will be described as an example.

The thickness of the low acoustic impedance layer 51 is defined as D2, and the thickness of the high acoustic impedance layer 52 is defined as D3.

All of the multiple low acoustic impedance layers 51 do not need to have the same thickness. For example, the thickness of the low acoustic impedance layer 51 may be thinner or may be thicker as the low acoustic impedance layer 51 is closer to the piezoelectric layer 2. Alternatively, only the low acoustic impedance layer 51 remote from the piezoelectric layer 2 may have a thickness different from that of the other low acoustic impedance layers 51. If the multiple low acoustic impedance layers 51 do not have the same thickness, the thickness of the closest low acoustic impedance layer 51 to the piezoelectric layer 2 may be defined as D2. Alternatively, the average of the thicknesses of the multiple low acoustic impedance layers 51 may be defined as D2.

All of the multiple high acoustic impedance layers 52 do not need to have the same thickness. For example, the thickness of the high acoustic impedance layer 52 may be thinner or may be thicker as the high acoustic impedance layer 52 is closer to the piezoelectric layer 2. Alternatively, only the high acoustic impedance layer 52 remote from the piezoelectric layer 2 may have a thickness different from that of the other high acoustic impedance layers 52. If the multiple high acoustic impedance layers 52 do not have the same thickness, the thickness of the closest high acoustic impedance layer 52 to the piezoelectric layer 2 may be defined as D3. Alternatively, the average of the thicknesses of the multiple high acoustic impedance layers 52 may be defined as D3.

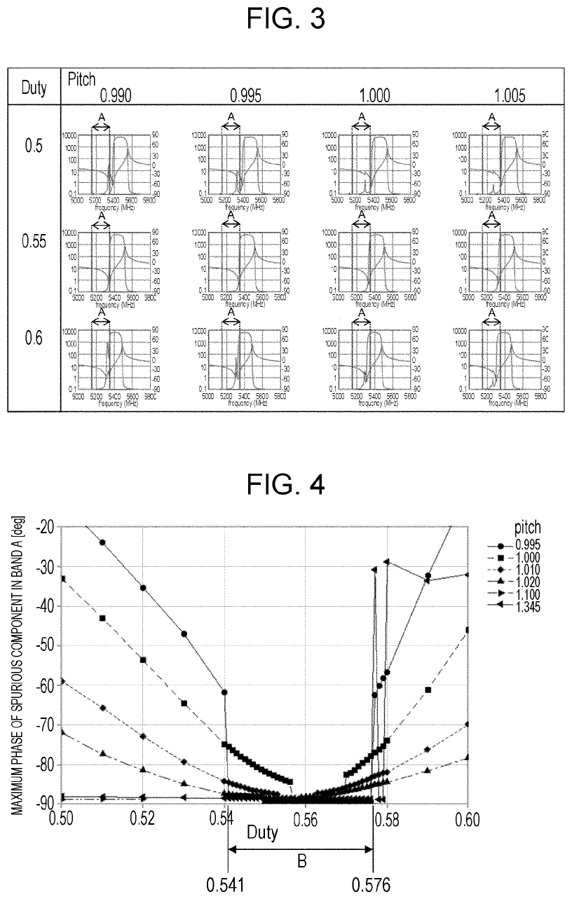

FIGS. 3 and 4 are graphs illustrating results of simulations with a variety of duties d of the electrode fingers and a variety of pitches p of the electrode fingers in the configuration in which the piezoelectric layer 2 is made of LT, the low acoustic impedance layer 51 is made of SiO₂, and the high acoustic impedance layer 52 is made of HfO₂.

FIG. 3 includes the graphs illustrating simulations of frequency characteristics under conditions where the pitch p of the electrode fingers was changed in a range of from 0.99 μm to 1.005 μm and the duty d was changed to values of 0.5, 0.55, and 0.6. In each graph of FIG. 3, the left vertical axis represents the absolute value of an impedance characteristic of a resonator, the right vertical axis represents a phase characteristic of the resonator, and the horizontal axis represents a frequency.

FIG. 3 demonstrates that spurious components in a frequency band A of from 5150 MHz to 5350 MHz at a duty d of 0.55 are lower than those at other duty values. The band A is substantially located on a low frequency side relative to a resonance frequency and can be regarded as a band having a width equivalent to the difference between the resonance frequency and an antiresonance frequency. Reduction of a spurious component in such a range improves, for example, the characteristics of a filter including the acoustic wave device 1. As an example, when the acoustic wave device 1 is included in a series-arm resonator of a ladder filter, which will be described later, the band A corresponds to an approximately half of the passband that is on the low frequency side, and a spurious component is reduced in this range.

Maximum phases of spurious components in the band A were obtained through simulations under conditions where the pitch p of the electrode fingers was changed in a range of from 0.99 μm to 1.35 μm and the duty d was changed in a range of from 0.5 to 0.6. FIG. 4 plots some of the above-described simulation results. For a waveform including no spurious component, a minimum phase value is depicted in FIG. 4.

In FIG. 4, the vertical axis represents the maximum phase of a spurious component in the band A, and the horizontal axis represents the duty d. In the simulations of FIG. 4, the thickness D1 of the piezoelectric layer 2, the thickness D2 of the low acoustic impedance layer 51, and the thickness D3 of the high acoustic impedance layer 52 were set as follows.
D1: 0.415 μm
D2: 0.15 μm
D3: 0.19 μm

FIG. 4 demonstrates that the maximum phases of spurious components are small in a range where the duty d ranges from 0.541 to 0.576. In other words, setting the duty d within the above-described range can reduce a spurious component, thus providing the acoustic wave device 1 with excellent filter characteristics.

When the pitch p of the electrode fingers is changed to a value ranging from 0.99 μm to 1.35 μm, a normalized thickness D1/p of the piezoelectric layer 2 normalized by the pitch p is expressed as a value ranging from 0.307 to 0.419. In obtaining D1/p, D1 and p are in the same unit, for example, in units of μm as described above. This note also applies to D2/p and D3/p, which will be described later.

The range of duty values of the electrode fingers from 0.541 to 0.576, where spurious components can be reduced, obtained from the simulations in FIG. 4 is referred to as a range B. In the range B, a maximum value of the duty d is 0.576, and a minimum value of the duty d is 0.541. In the range B, the normalized thickness D1/p of the piezoelectric layer 2 has a maximum value of 0.419 and a minimum value of 0.307 under conditions where the pitch p of the electrode fingers was changed to a value ranging from 0.99 μm to 1.35 μm.

A maximum value of the product (d×D1/p) of d and D1/p in the range B is 0.241. A minimum value of the product (d×D1/p) of d and D1/p in the range B is 0.166. The maximum value of d×D1/p is the product of a maximum value of d and a maximum value of D1/p. The minimum value of d×D1/p is the product of a minimum value of d and a minimum value of D1/p. Table 1 provides a summary of the above numerical values.

TABLE 1
Duty × LT[p]

| | d | D1/p | d × D1/p |
|---|---|---|---|
| min | 0.541 | 0.307 | 0.166 |
| max | 0.576 | 0.419 | 0.241 |

Specifically, the range of d×D1/p is expressed by inequality (1) below.

$$0.166 \leq d \times D 1 / p \leq 0.241 \qquad ( 1 )$$

If the value of d×D1/p lies within the above-described range, the maximum phase of a spurious component in the band A can be reduced.

When the pitch p of the electrode fingers is changed to a value ranging from 0.99 μm to 1.35 μm, a thickness D2/p of the low acoustic impedance layer 51 normalized by the pitch p is expressed as a value ranging from 0.111 to 0.152.

In the range B, the maximum value of the duty d is 0.576, and the minimum value of the duty d is 0.541. In the range B, the normalized thickness D2/p of the low acoustic impedance layer 51 has a maximum value of 0.152 and a minimum value of 0.111 under conditions where the pitch p of the electrode fingers was changed to a value ranging from 0.99 μm to 1.35 μm.

A maximum value of the product (d×D2/p) of d and D2/p in the range B is 0.087. A minimum value of the product (d×D2/p) of d and D2/p in the range B is 0.06. The maximum value of d×D2/p is the product of a maximum value of d and a maximum value of D2/p. The minimum value of d×D2/p is the product of a minimum value of d and a minimum value of D2/p. Table 2 provides a summary of the above numerical values.

TABLE 2
Duty × SiO₂[p]

| | d | D2/p | d × D2/p |
|---|---|---|---|
| min | 0.541 | 0.111 | 0.06 |
| max | 0.576 | 0.152 | 0.087 |

Specifically, the range of d×D2/p is expressed by inequality (2) below.

$$0.060 \leq d \times D 2 / p \leq 0.087 \qquad ( 2 )$$

If the value of d×D2/p lies within the above-described range, the maximum phase of a spurious component in the band A can be reduced.

When the pitch p of the electrode fingers is changed to a value ranging from 0.99 μm to 1.35 μm, the thickness D3 of the high acoustic impedance layer 52 normalized by the pitch p is expressed as a value ranging from 0.141 to 0.192.

In the range B, the maximum value of the duty d is 0.576, and the minimum value of the duty d is 0.541. In the range B, a normalized thickness D3/p of the high acoustic impedance layer 52 has a maximum value of 0.192 and a minimum value of 0.141 under conditions where the pitch p of the electrode fingers was changed to a value ranging from 0.99 μm to 1.35 μm.

A maximum value of the product (d×D3/p) of d and D3/p in the range B is 0.111. A minimum value of the product (d×D3/p) of d and D3/p in the range B is 0.076. The maximum value of d×D3/p is the product of a maximum value of d and a maximum value of D3/p. The minimum value of d×D3/p is the product of a minimum value of d and a minimum value of D3/p. Table 3 provides a summary of the above numerical values.

TABLE 3
Duty × HfO₂[p]

| | d | D3/p | d × D3/p |
|---|---|---|---|
| min | 0.541 | 0.141 | 0.076 |
| max | 0.576 | 0.192 | 0.111 |

Specifically, the range of d×D3/p is expressed by inequality (3) described below.

$$0.076 \leq d \times D 3 / p \leq 0 \text{.111} \qquad ( 3 )$$

If the value of d×D3/p lies within the above-described range, the maximum phase of a spurious component in the band A can be reduced.

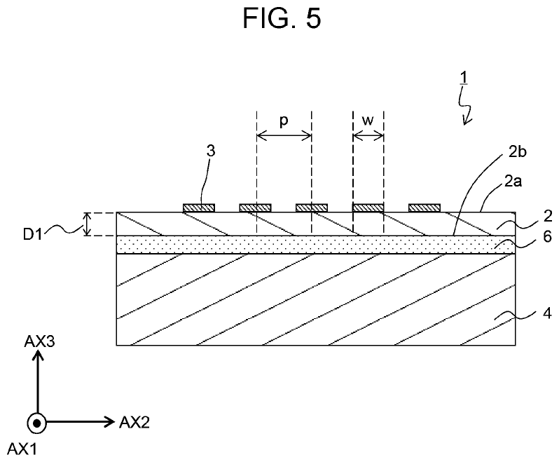

In the above-described exemplary configuration, the acoustic wave device 1 includes the multilayer film 5. The configuration is not limited to this example. For example, the configuration may exclude the multilayer film 5. As illustrated in FIG. 5, the configuration may include the intermediate layer 6 instead of the multilayer film 5.

The intermediate layer 6 is made of an insulative material, such as silicon oxide (SiO₂), silicon nitride (Si₃N₄), or aluminum oxide (Al₂O₃), and may have any crystallinity. The intermediate layer 6 can reduce the generation of an unnecessary potential and the formation of an unnecessary capacitance. This leads to improved electrical characteristics of the acoustic wave device 1.

Furthermore, the intermediate layer 6 made of a material having a lower acoustic velocity than the material forming the piezoelectric layer 2 can increase the robustness of the piezoelectric layer 2 to a change in thickness of the piezoelectric layer 2.

In another embodiment, the supporting substrate 4 may include a recess 7 in an upper surface thereof. In such a configuration, the piezoelectric layer 2 covers the recess 7 of the supporting substrate 4 in plan view to leave a space in the recess 7.

The size and depth of the recess 7 may be set as appropriate.

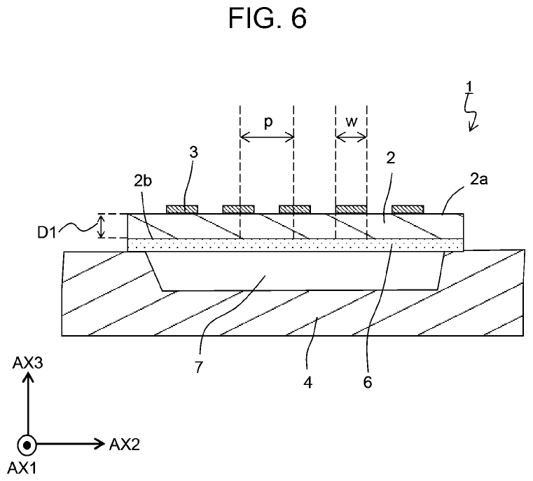

As illustrated in FIG. 6, the intermediate layer 6 may be located on the upper surface of the supporting substrate 4 including the recess 7. In such a configuration, the intermediate layer 6 and the piezoelectric layer 2 cover the recess 7 of the supporting substrate 4 in plan view to leave a space in the recess 7.

The multilayer film 5 may be located on the upper surface of the supporting substrate 4 including the recess 7. In such a configuration, the multilayer film 5 and the piezoelectric layer 2 cover the recess 7 of the supporting substrate 4 in plan view to leave a space in the recess 7.

The configuration may further include a substrate (not illustrated) located on a lower surface side of the supporting substrate 4 including the recess 7.

For the band A (predetermined range substantially on the low frequency side relative to the resonance frequency), a range of from 5150 MHz to 5350 MHz has been described as an example. Since the configuration is determined by normalized parameters, or the duty d and the normalized thickness D1/p, in inequality (1), spurious components are reduced not only in the range of from 5150 MHZ to 5350 MHz but also in various specific frequency bands, each serving as the band A. The same applies to inequality (2) and inequality (3).

More strictly speaking, a spurious component in the band A is affected by parameters other than d and D1/p (or D2/p or D3/p). Therefore, if the other parameters have values different from those used when the characteristics illustrated in FIG. 4 were obtained, the same characteristics as those in FIG. 4 will not be obtained. In this case, however, a tendency similar to that in FIG. 4 can be obtained. In other words, if any of inequalities (1) to (3) is satisfied, the best characteristics may not necessarily be obtained, but the probability that better characteristics may be obtained increases. From this point of view, the other parameters may have any value.

The values of the other parameters may be the same as or close to those used when the characteristics in FIG. 4 were obtained. For example, the acoustic wave propagation direction (along the AX2 axis) may be a direction in which an inclination angle of the piezoelectric layer 2 in any direction relative to the X axis is 0°±5° or 0°±1°. The piezoelectric layer 2 may be with a 114°±5° rotated Y-cut or a 114°±1° rotated Y-cut. Empirically, as long as the difference is less than or equal to 5° or is less than or equal to 1°, the characteristics related to a spurious component do not change significantly. For the IDT electrode 3 used when the characteristics in FIG. 4 were obtained, the IDT electrode 3 contains, as a main component, (50 mass % or more) Al and has a thickness of 130 nm. When this thickness is normalized by the pitch p ranging from 0.99 μm to 1.35 μm in a manner similar to the thicknesses D1 to D3, the normalized thickness ranges from 0.096 to 0.132. The normalized thickness of the IDT electrode 3 may lie within the above-described range or may lie within a range of from 0.05 to 0.2 including the above-described range.

### (Exemplary Application of Acoustic Wave Device 1: Duplexer)

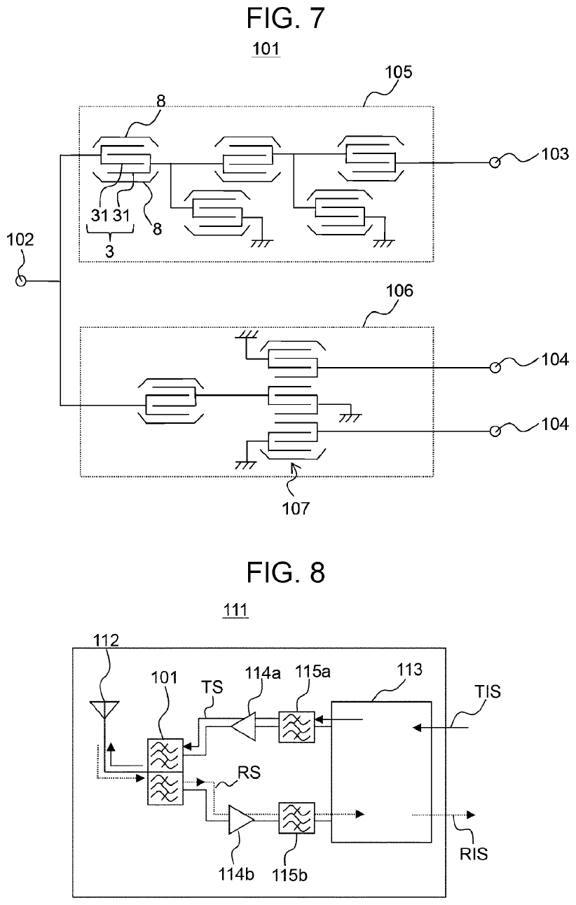

FIG. 7 is a schematic circuit diagram of the configuration of a duplexer 101 as an exemplary application of the acoustic wave device 1. As will be understood from the reference signs illustrated in an upper left part of the drawing sheet of FIG. 7, the comb-shaped electrodes 31 are schematically illustrated in a two-pronged fork shape. Each of the reflectors 8 is represented by a single line with opposite bent ends.

The duplexer 101 includes, for example, a transmit filter 105 and a receive filter 106. The transmit filter 105 filters a transmit signal from a transmit terminal 103 and outputs the signal to an antenna terminal 102. The receive filter 106 filters a receive signal from the antenna terminal 102 and outputs the signal to a pair of receive terminals 104.

The transmit filter 105 includes, for example, a ladder filter including multiple resonators connected in a ladder shape. Specifically, the transmit filter 105 includes multiple (one or more) resonators connected in series between the transmit terminal 103 and the antenna terminal 102 and multiple (one or more) resonators (parallel arms) connecting the series line (series arm) to the ground potential.

The receive filter 106 includes, for example, a resonator and a multi-mode filter (including a double-mode filter) 107. The multi-mode filter 11 includes multiple (three in the example of FIG. 7) IDT electrodes 3 arranged in the acoustic wave propagation direction and two reflectors 8 disposed at opposite sides of the arrangement of the IDT electrodes 3.

FIG. 7 illustrates an exemplary configuration of the duplexer 101. For example, like the transmit filter 105, the receive filter 106 may include a ladder filter.

The duplexer 101 including the transmit filter 105 and the receive filter 106 has been described as an example. The duplexer 101 may have any configuration. For example, the duplexer 101 may be a diplexer or may be a multiplexer including three or more filters.

### (Exemplary Application of Acoustic Wave Device 1: Communication Apparatus)

FIG. 8 is a block diagram illustrating an essential part of a communication apparatus 111 as an exemplary application of the acoustic wave device 1 (duplexer 101). The communication apparatus 111, which performs wireless communication using radio waves, includes the duplexer 101.

In the communication apparatus 111, a radio frequency integrated circuit (RF-IC) 113 modulates a transmit information signal TIS containing information to be transmitted and raises the frequency of the transmit information signal TIS into a transmit signal TS (by converting the signal to a radio-frequency signal with a carrier frequency). A bandpass filter 115a removes, from the transmit signal TS, unnecessary components outside a transmit passband. An amplifier 114a amplifies the transmit signal TS. The transmit signal TS is inputted to the duplexer 101 (transmit terminal 103). The duplexer 101 (transmit filter 105) removes unnecessary components outside the transmit passband from the inputted transmit signal TS. The resultant transmit signal TS is outputted from the antenna terminal 102 to an antenna 112. The antenna 112 converts the inputted electrical signal (transmit signal TS) into a radio signal (radio wave) and transmits the signal.

In the communication apparatus 111, the antenna 112 receives a radio signal (radio wave) and converts the signal into an electrical signal (receive signal RS). The resultant signal is inputted to the duplexer 101 (antenna terminal 102). The duplexer 101 (receive filter 106) removes unnecessary components outside a receive passband from the inputted receive signal RS. The resultant signal is outputted from the receive terminals 104 to an amplifier 114b. The amplifier 114b amplifies the outputted receive signal RS. A bandpass filter 115b removes unnecessary components outside the receive passband from the receive signal RS. The RF-IC 113 lowers the frequency of the receive signal RS and demodulates the signal into a receive information signal RIS.

The transmit information signal TIS and the receive information signal RIS may be low-frequency signals (baseband signals) containing appropriate information, for example, analog audio signals or digital audio signals. The passband for radio signals may be set as appropriate. In the embodiment, a relatively high frequency passband (of 5 GHz or higher, for example) can also be used. The method of modulation may be phase modulation, amplitude modulation, frequency modulation, or a combination of two or more of these methods of modulation. Although FIG. 8 illustrates a direct conversion circuit as an example, the circuit may be any other appropriate circuit, for example, a double superheterodyne circuit. FIG. 8 schematically illustrates only the essential part. The circuit may further include a low-pass filter or an isolator at an appropriate position. For example, the positions of the amplifiers may be changed.

### REFERENCE SIGNS

1 acoustic wave device
2 piezoelectric layer
2a upper surface
2b lower surface
3 IDT electrode
31 comb-shaped electrode
311 bus bar
312 electrode finger
4 supporting substrate
5 multilayer film
51 low acoustic impedance layer
52 high acoustic impedance layer
6 intermediate layer
7 recess
8 reflector
81 reflector bus bar
82 strip electrode
101 duplexer
102 antenna terminal
103 transmit terminal
104 receive terminal
105 transmit filter
106 receive filter
107 multi-mode filter
111 communication apparatus
112 antenna
113 RF-IC
114 amplifier
115 bandpass filter

1. An acoustic wave device comprising:
a piezoelectric layer comprising a piezoelectric crystal; and
an interdigital transducer (IDT) electrode on an upper surface of the piezoelectric layer, the IDT electrode comprising multiple electrode fingers,
wherein a normalized thickness D1/p of the piezoelectric layer and a duty d of the IDT electrode have a relationship expressed by inequality (1) below
$$0.166 \leq d \times D 1 / p \leq 0.241 , \qquad ( 1 )$$
where
p is a repetition interval between centers of the multiple electrode fingers, and
D1 is a thickness of the piezoelectric layer.

2. An acoustic wave device comprising:
a piezoelectric layer comprising a piezoelectric crystal;
an IDT electrode on an upper surface of the piezoelectric layer, the IDT electrode comprising multiple electrode fingers; and
a multilayer film on a lower surface side of the piezoelectric layer, the multilayer film comprising at least one low acoustic impedance layer and at least one high acoustic impedance layer alternated with each other,
wherein a normalized thickness D2/p of the low acoustic impedance layer and a duty d of the IDT electrode have a relationship expressed by inequality (2) below
$$0.060 \leq d \times D 2 / p \leq 0.087 , \qquad ( 2 )$$
where
p is a repetition interval between centers of the multiple electrode fingers, and
D2 is a thickness of the low acoustic impedance layer.

3. An acoustic wave device comprising:
a piezoelectric layer comprising a piezoelectric crystal;
an IDT electrode on an upper surface of the piezoelectric layer, the IDT electrode comprising multiple electrode fingers; and
a multilayer film on a lower surface side of the piezoelectric layer, the multilayer film comprising at least one low acoustic impedance layer and at least one high acoustic impedance layer alternated with each other,
wherein a normalized thickness D3/p of the high acoustic impedance layer and a duty d of the IDT electrode have a relationship expressed by inequality (3) below
$$0.076 \leq d \times D 3 / p \leq 0.1 \; 11 , \qquad ( 3 )$$
where
p is a repetition interval between centers of the multiple electrode fingers, and
D3 is a thickness of the high acoustic impedance layer.

4. The acoustic wave device according to claim 1, wherein the duty d of the IDT electrode ranges from 0.541 to 0.576.

5. The acoustic wave device according to claim 1, further comprising:
a supporting substrate on a lower surface side of the piezoelectric layer.

6. The acoustic wave device according to claim 2, wherein
the low acoustic impedance layer comprises SiO₂, and
the high acoustic impedance layer comprises HfO₂.

7. The acoustic wave device according to claim 1, wherein
the supporting substrate includes a recess in an upper surface of the supporting substrate, and
the piezoelectric layer covers the recess of the supporting substrate in plan view.

8. A duplexer comprising:
an antenna terminal;
a transmit filter configured to filter a signal to be outputted to the antenna terminal; and
a receive filter configured to filter a signal inputted from the antenna terminal,
wherein at least one of the transmit filter or the receive filter comprises the acoustic wave device according to claim 1.

9. A communication apparatus comprising:
an antenna;
the duplexer according to claim 8 with the antenna terminal connected to the antenna; and
an integrated circuit (IC) connected to the transmit filter and the receive filter, wherein the IC and the antenna terminal are located at opposite sides of the transmit and receive filters in a signal path.
